(19) United States
(12) Patent Application Publication
(10) Pub. No.: US 2025/0126808 A1
(43) Pub. Date: Apr. 17, 2025

(54) CMOS DEVICE WITH MULTIPLE CHANNELS VERTICALLY STACKED

(71) Applicant: UIF (University Industry Foundation), Yonsei University, Seoul (KR)

(72) Inventors: Jiwon Chang, Seoul (KR); Changwook Lee, Seoul (KR); Jae Eun Seo, Hwaseong-si (KR)

(21) Appl. No.: 18/906,185

(22) Filed: Oct. 4, 2024

(30) Foreign Application Priority Data
Oct. 11, 2023 (KR) 10-2023-0134899

(51) Int. Cl. H10B 63/00; H10B 63/10; H10N 70/00; H10N 70/20

(52) U.S. Cl. CPC H10B 63/84; H10B 63/10; H10N 70/011; H10N 70/231; H10N 70/253; H10N 70/8825

(57) ABSTRACT

A ternary CMOS device includes a common gate terminal configured such that an input voltage is applied to the common gate terminal, and two MOSFET regions, wherein each of the MOSFET regions includes a two-dimensional phase change material layer formed of a two-dimensional phase change material, a two-dimensional semiconductor material layer formed of a two-dimensional semiconductor material having a characteristic of changing into a conductor by a voltage change without separate doping and stacked on either a top or bottom of the two-dimensional phase change material layer, a common drain terminal connected to one end of the two-dimensional phase change material layer and one end of the two-dimensional semiconductor material layer, and a source terminal connected to the other end of the two-dimensional phase change material layer and the other end of the two-dimensional semiconductor material layer.

### CROSS-REFERENCE TO RELATED APPLICATIONS

This application claims priority under 35 U.S.C. § 119 to Korean Patent Application No. 10-2023-0134899 filed on Oct. 11, 2023, in the Korean Intellectual Property Office, the disclosures of which are incorporated by reference herein in their entireties.

### BACKGROUND

Embodiments of the present disclosure described herein relate to a CMOS device that enables ternary operation.

The present disclosure is derived from a basic personal study (Project Identification Number: 1711181765, Project Number: 2022R1A2C2008726, Research Project Name: Research on Ternary CMOS technology capable of monolithic 3D integration using phase transition according to the thickness of 2D materials to implement logic-in-memory, Project Management Agency: National Research Foundation of Korea, Research Period: from Mar. 1, 2023 to Feb. 29, 2024) conducted by the Ministry of Science and ICT. On the other hand, there is no property interest of the Korean government in any aspect of the present disclosure.

A CMOS (Complementary Metal-Oxide Semiconductor) is a type of integrated circuit and is widely used in the circuits of most electronic devices. The CMOS is a device in which a p-channel MOSFET (p-MOS) and an n-channel MOSFET (n-MOS) are formed on a single chip, with the p-channel MOS and the n-channel MOS operating in a complementary manner. The CMOS is mainly used to configure integrated circuits such as microprocessors, SRAM (Static Random Access Memory), and image sensors. The CMOS is widely used because the CMOS is cheaper than a process using a BJT device and is able to implement low-power circuits.

In recent years, semiconductor device technology has been actively researched to address the question of how much power consumption may be reduced. However, there is a fundamental problem in that it is difficult to solve the power consumption problem in large-scale information processing such as big data using binary elements that express information in the binary notation of 0 and 1.

### SUMMARY

Embodiments of the present disclosure provide a ternary CMOS device capable of performing ternary operations.

In addition, the present disclosure provides a ternary CMOS device based on a two-dimensional material that is available for various purposes from an ultra-low power environment to a high-performance environment by supporting a wide range of operating speeds.

In addition, embodiments of the present disclosure provide a ternary CMOS device capable of implementing a constant current more robustly and stably because there is no process dispersion due to doping.

In addition, embodiments of the present disclosure provide a ternary CMOS device capable of using a semiconductor material capable of enabling top integration under process conditions that do not deteriorate the characteristics and reliability of Si-based CMOS to increase the integration density of a device.

Meanwhile, the technical problems to be solved by the present disclosure are not limited to the aforementioned problems, and any other technical problems not mentioned herein will be clearly understood from the following description by those skilled in the art to which the present disclosure pertains.

According to an embodiment, a ternary CMOS device includes a common gate terminal configured such that an input voltage is applied to the common gate terminal, and two MOSFET regions, wherein each of the MOSFET regions includes a two-dimensional phase change material layer formed of a two-dimensional phase change material, a two-dimensional semiconductor material layer formed of a two-dimensional semiconductor material having a characteristic of changing into a conductor by a voltage change without separate doping and stacked on either a top or bottom of the two-dimensional phase change material layer, a common drain terminal connected to one end of the two-dimensional phase change material layer and one end of the two-dimensional semiconductor material layer, and a source terminal connected to the other end of the two-dimensional phase change material layer and the other end of the two-dimensional semiconductor material layer.

The two-dimensional phase change material layer may allow a constant current to flow between the common drain terminal and the source terminal regardless of a magnitude of a voltage applied to the common gate terminal.

The two-dimensional phase change material layer may be formed of a two-dimensional phase change material having a decreasing band gap as a thickness of the layer increases.

The two-dimensional phase change material layer may be formed of transition metal dichalcogenides (TMDs) having a decreasing band gap as the thickness of the layer increases.

The two-dimensional phase change material layer may be formed of at least one of PtSe₂ (Platinum Diselenide) and PdSe₂ (Palladium Diselenide).

The two-dimensional phase change material layer may be formed of at least one of arsenene which is a two-dimensional phase change material composed of single atoms, is an allotrope of arsenic (As) and has a two-dimensional structure, and antimonene which is a two-dimensional phase change material composed of single atoms, is an allotrope of antimony (Sb) and has a two-dimensional structure.

The ternary CMOS device may further include a first oxide material layer stacked between the two-dimensional semiconductor material layer and the common gate terminal to be positioned between the two-dimensional semiconductor material layer and the common gate terminal.

The ternary CMOS device may further include a second oxide material layer stacked between the two-dimensional phase change material layer and the two-dimensional semiconductor material layer to be positioned between the two-dimensional phase change material layer and the two-dimensional semiconductor material layer.

One of the two MOSFET regions may be an n-type ternary MOSFET region and the other of the two MOSFET regions may be a p-type ternary MOSFET region. The n-type ternary MOSFET region may include an n-channel two-dimensional semiconductor material layer formed of a two-dimensional semiconductor material having a characteristic of changing into an n-type conductor by a voltage change without separate doping. The p-type ternary MOSFET region may include a p-channel two-dimensional semiconductor material layer formed of a two-dimensional semiconductor material having a characteristic of changing into a p-type conductor by a voltage change without separate doping.

The n-type ternary MOSFET region may include an n-channel-side two-dimensional phase change material layer formed of a two-dimensional phase change material stacked on either a top or bottom of the n-channel two-dimensional semiconductor material layer, and a first source terminal connected to the other end of the n-channel-side two-dimensional phase change material layer and the other end of the n-channel two-dimensional semiconductor material layer. The n-channel two-dimensional semiconductor material layer may be provided between the first source terminal and the common drain terminal. The n-channel-side two-dimensional phase change material layer may be provided between the first source terminal and the common drain terminal to allow a constant current to flow between the common drain terminal and the first source terminal regardless of a magnitude of a voltage applied to the common gate terminal.

The p-type ternary MOSFET region may include an p-channel-side two-dimensional phase change material layer formed of a two-dimensional phase change material stacked on either a top or bottom of the p-channel two-dimensional semiconductor material layer, and a second source terminal connected to the other end of the p-channel-side two-dimensional phase change material layer and the other end of the p-channel two-dimensional semiconductor material layer. The p-channel two-dimensional semiconductor material layer may be provided between the second source terminal and the common drain terminal. The p-channel-side two-dimensional phase change material layer may be provided between the second source terminal and the common drain terminal to allow a constant current to flow between the common drain terminal and the second source terminal regardless of a magnitude of a voltage applied to the common gate terminal.

The ternary CMOS device may further include a CMOS input terminal connected to the common gate terminal and configured to input a common input voltage to the common gate terminal, and a CMOS output terminal connected to the common drain terminal and configured to output a common output voltage.

The CMOS output terminal may output a maximum voltage with a predetermined magnitude when a voltage input to the CMOS input terminal is less than a first reference voltage, output an intermediate voltage with a predetermined magnitude when the voltage input to the CMOS input terminal is greater than or equal to a second reference voltage and less than or equal to a third reference voltage, and output no voltage when the voltage input to the CMOS input terminal is greater than or equal to a fourth reference voltage.

The n-type ternary MOSFET region may be stacked on a bottom of the common gate terminal, and the p-type ternary MOSFET region may be stacked on a top of the common gate terminal.

The n-type ternary MOSFET region may further include an n-channel-side first oxide material layer. The n-channel two-dimensional semiconductor material layer may be stacked on a top of the n-channel-side two-dimensional phase change material layer. The n-channel-side first oxide material layer may be stacked on a top of the n-channel two-dimensional semiconductor material layer. The common gate terminal may be connected to a top of the n-channel-side first oxide material layer.

The p-type ternary MOSFET region may further include a p-channel-side first oxide material layer. The p-channel two-dimensional semiconductor material layer may be stacked on a bottom of the p-channel-side two-dimensional phase change material layer. The p-channel-side first oxide material layer may be stacked on a bottom of the p-channel two-dimensional semiconductor material layer. The common gate terminal may be connected to a bottom of the p-channel-side first oxide material layer and provided between the p-type ternary MOSFET region and the n-type ternary MOSFET region.

The ternary CMOS device may further include a first spacer formed of an insulating material, connected to the common gate terminal at one end of the first spacer, and provided between the p-type ternary MOSFET region and the n-type ternary MOSFET region, and a second spacer formed of an insulating material, connected to the common gate terminal at one end of the second spacer, connected to the common drain terminal at the other end of the second spacer, and provided between the p-type ternary MOSFET region and the n-type ternary MOSFET region. The first spacer may be stacked on a top of the first source terminal and a top of the n-channel-side first oxide material layer, and on a bottom of the second source terminal and a bottom of the p-channel-side first oxide material layer. The second spacer may be stacked on the top of the n-channel-side first oxide material layer, and on the bottom of the p-channel-side first oxide material layer.

According to an embodiment, a method of fabricating the ternary CMOS device includes depositing the n-channel two-dimensional semiconductor material layer on a top of the n-channel-side two-dimensional phase change material layer, and depositing the n-channel-side first oxide material layer on a top of the n-channel two-dimensional semiconductor material layer.

The method may further include depositing the first spacer and the second spacer on the top of the n-channel-side first oxide material layer, and connecting the common gate terminal to the top of the n-channel-side first oxide material layer.

The method may further include depositing the p-channel-side first oxide material layer on a top of the common gate terminal, a top of the first spacer, and a top of the second spacer, depositing the p-channel two-dimensional semiconductor material layer on a top of the p-channel-side first oxide material layer, and depositing the p-channel-side two-dimensional phase change material layer on the top of the p-channel two-dimensional semiconductor material layer.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a diagram illustrating a ternary CMOS device according to an embodiment;

FIG. 2 is a diagram showing a ternary CMOS device including a second oxide material layer according to an embodiment.

FIG. 3 is a diagram illustrating two-dimensional phase change materials;

FIG. 4 is a graph for describing a two-dimensional phase change material having a decreasing band gap with increasing thickness;

FIG. 5 is a graph for describing a two-dimensional phase change material having an increasing conductivity with increasing thickness;

FIG. 6 is a diagram illustrating three states implemented in a ternary inverter;

FIG. 7 is a diagram for describing a ternary device in which circuit complexity decreases with an increase in logic digits compared to the prior art;

FIG. 8 is a diagram for describing a simplification of an artificial neural network connection by the introduction of a ternary device;

FIG. 9 is a circuit diagram showing the characteristics of a ternary CMOS device according to an embodiment;

FIG. 10 is a graph showing a current flowing via a ternary CMOS device according to a voltage applied to the gate; and

FIG. 11 is a graph showing the input/output characteristics of a ternary CMOS device according to an embodiment.

### DETAILED DESCRIPTION OF EXEMPLARY EMBODIMENTS

Hereinafter, the feature of the present disclosure will be described in detail with reference to exemplary embodiments and accompanying drawings to clarify solutions of problems to be solved according to the present disclosure. In the following description, the same reference numerals will be assigned to the same components even though the components are illustrated in different drawings. In addition, when the description is made with reference to a present drawing, a component in another drawing may be cited if necessary.

Directional terms such as “upper side”, “lower side”, “one side”, and “other side” are used in relation to the orientations in the disclosed drawings. Since components of the embodiments of the present disclosure may be positioned in various orientations, the directional terms are merely illustrative and do not limit the components.

In addition, throughout the specification, unless explicitly described to the contrary, the word “comprise” and variations such as “comprises” or “comprising” will be understood to imply the inclusion of stated elements but not the exclusion of any other elements. In the above description, when a part is connected to the other part, the parts are not only directly connected to each other, but also indirectly connected to each other while interposing another part therebetween.

Terms such as first and second are used to distinguish one component from another component, and the components are not limited by the above-mentioned terms. As used herein, singular forms may include plural forms as well unless the context clearly indicates otherwise.

In each step, identification symbols are used for convenience of description and the identification symbols do not describe the order of the steps and the steps may be performed in a different order from the described order unless the context clearly indicates a specific order.

Hereinafter, embodiments of the present disclosure will be described in detail with reference to the exemplary drawings. The embodiments of the present disclosure may be modified in various forms, and the scope of the present disclosure should not be construed as being limited to the embodiments below. The present embodiments are provided to more completely explain the present disclosure to those with average knowledge in the art. Therefore, the shapes of the elements in the drawings are exaggerated to emphasize a clearer explanation.

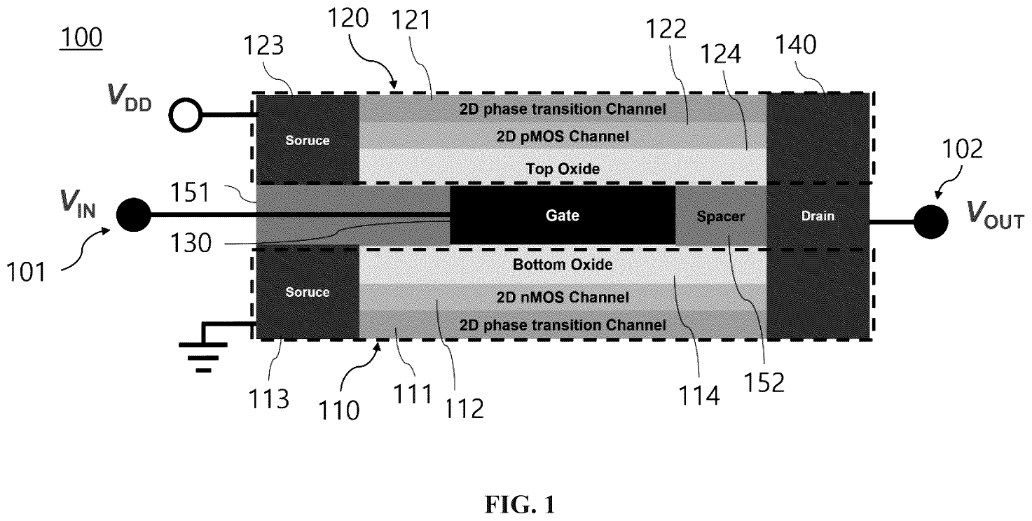

FIG. 1 is a diagram illustrating a ternary CMOS device according to an embodiment;

Referring to FIG. 1, a ternary CMOS device 100 may be composed of two MOSFET regions 110 and 120, and a common gate terminal 130.

The ternary CMOS device 100 may be a CMOS device capable of performing a ternary operation, unlike a conventional CMOS device that generally performs a binary operation.

An input voltage may be applied to the common gate terminal 130.

Each of the MOSFET regions may include a two-dimensional phase change material layer, a two-dimensional semiconductor material layer, a common drain terminal 140, a source terminal, and a first oxide material layer.

The two-dimensional phase change material layer may be formed of a two-dimensional phase change material. The two-dimensional phase change material layer may be configured such that a constant current flows between the common drain terminal 140 and the source terminal regardless of the magnitude of an input voltage VIN applied to the common gate terminal 130.

The two-dimensional semiconductor material layer may be formed of a two-dimensional semiconductor material that has the property of changing into a conductor by a voltage change without separate doping. The two-dimensional semiconductor material layer may be stacked on either the top or bottom of the two-dimensional phase change material layer.

The two-dimensional semiconductor material layer may be formed of a two-dimensional semiconductor material that has the property of changing into a conductor by a voltage change without separate doping.

The two-dimensional semiconductor material is transition-metal dicalcogenides (TMDCs), which have a layered structure with one transition metal atom and two chalcogen atoms, and may be either single or multiple layers of crystalline material with atomic layers.

The two-dimensional semiconductor material has an insulator characteristic under normal conditions, but may show a characteristic of changing into a conductor when an electric field is applied. In other words, the two-dimensional semiconductor material may be a material that has a specific polarity only by a voltage change without separate doping.

The common drain terminal 140 may be connected to one end of the two-dimensional phase change material layer and one end of the two-dimensional semiconductor material layer.

The source terminal may be connected to the other end of the two-dimensional phase change material layer and the other end of the two-dimensional semiconductor material layer.

The first oxide material layer may be stacked between the two-dimensional semiconductor material layer and the common gate terminal 130 such that the first oxide material layer is positioned between the two-dimensional semiconductor material layer and the common gate terminal 130.

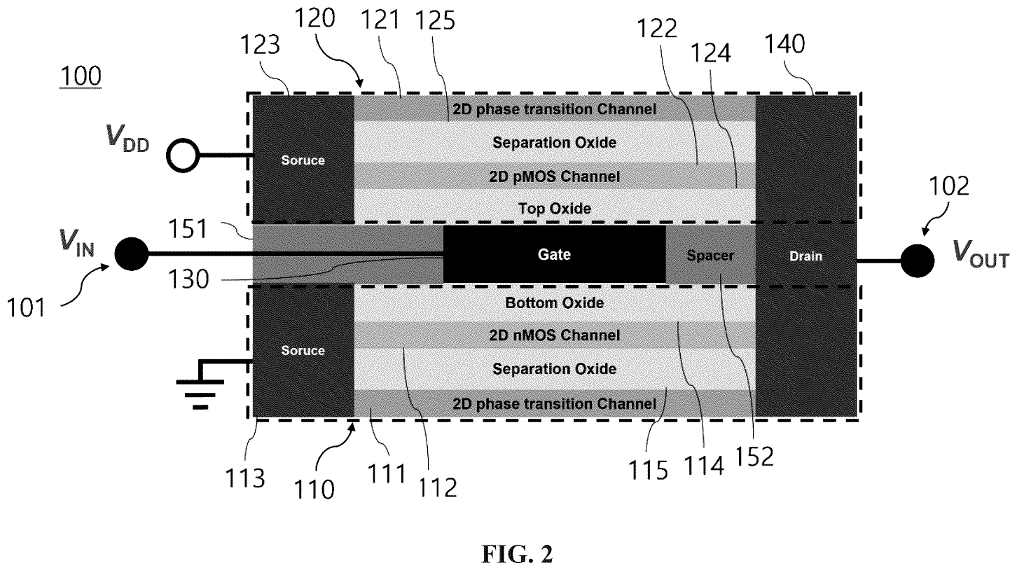

FIG. 2 is a diagram showing a ternary CMOS device including a second oxide material layer according to an embodiment.

Referring to FIG. 2, each of the MOSFET regions may further include a second oxide material layer.

The second oxide material layer may be stacked between the two-dimensional phase change material layer and the two-dimensional semiconductor material layer to be positioned between the two-dimensional phase change material layer and the two-dimensional semiconductor material layer.

Referring to FIG. 1 and FIG. 2, one of the two MOSFET regions may be an p110 and the other MOSFET region may be a p-type ternary MOSFET region 120.

In this case, the n-type ternary MOSFET region 110 may be positioned at the bottom and the p-type ternary MOSFET region 120 may be positioned at the top. However, it should be noted that the n-type ternary MOSFET region 110 may be positioned at the top and the p-type ternary MOSFET region 120 may be positioned at the bottom.

The n-type ternary MOSFET region 110 may include an n-channel-side two-dimensional phase change material layer 111, an n-channel two-dimensional semiconductor material layer 112, a first source terminal 113, an n-channel-side first oxide material layer 114, and the common drain terminal 140.

The n-channel two-dimensional semiconductor material layer 112 may be a two-dimensional semiconductor material layer formed of a two-dimensional semiconductor material that has a characteristic of changing into an n-type conductor by a voltage change without separate doping.

The n-channel two-dimensional semiconductor material layer 112 may be an n-channel of CMOS. In this case, the n-channel two-dimensional semiconductor material layer 112 may be made of MoS₂, but is not limited thereto and it may be possible that various materials capable of forming an n-channel among two-dimensional semiconductor materials are used.

The n-channel-side two-dimensional phase change material layer 111 may be a two-dimensional phase change material layer formed of a two-dimensional phase change material that is stacked on either the top or bottom of the n-channel two-dimensional semiconductor material layer 112.

The first source terminal 113 may be a source terminal connected to the other end of the n-channel-side two-dimensional phase change material layer 111 and the other end of the n-channel two-dimensional semiconductor material layer 112. The first source terminal 113 may be electrically connected to ground.

The n-channel two-dimensional semiconductor material layer 112 may be provided between the first source terminal 113 and the common drain terminal 140.

The n-channel-side two-dimensional phase change material layer 111 may be provided between the first source terminal 113 and the common drain terminal 140. The n-channel-side two-dimensional phase change material layer 111 may be configured to allow a constant current to flow between the common drain terminal 140 and the first source terminal 113 regardless of the magnitude of a voltage applied to the common gate terminal 130.

The p-type ternary MOSFET region 120 may include a p-channel-side two-dimensional phase change material layer 121, a p-channel two-dimensional semiconductor material layer 122, a second source terminal 123, a p-channel-side first oxide material layer 124, and the common drain terminal 140.

The p-channel two-dimensional semiconductor material layer 122 may be a two-dimensional semiconductor material layer formed of a two-dimensional semiconductor material having a characteristic of changing into a p-type conductor by a voltage change without separate doping.

The p-channel two-dimensional semiconductor material layer 122 may be a p-channel of CMOS. In this case, the p-channel two-dimensional semiconductor material layer 122 may be made of WSe₂, but is not limited thereto, and it may be possible that various materials capable of forming a p-channel among two-dimensional semiconductor materials are used.

The p-channel-side two-dimensional phase change material layer 121 may be a two-dimensional phase change material layer formed of a two-dimensional phase change material that is stacked on either the top or bottom of the p-channel two-dimensional semiconductor material layer 122.

The second source terminal 123 may be connected to the other end of the p-channel-side two-dimensional phase change material layer 121 and the other end of the p-channel two-dimensional semiconductor material layer 122. The second source terminal 123 may be applied with a power supply voltage V_{DD}.

The p-channel two-dimensional semiconductor material layer 122 may be provided between the second source terminal 123 and the common drain terminal 140.

The p-channel-side two-dimensional phase change material layer 121 may be provided between the second source terminal 123 and the common drain terminal 140. The p-channel-side two-dimensional phase change material layer 121 may be configured to allow a constant current to flow between the common drain terminal 140 and the second source terminal 123 regardless of the magnitude of a voltage applied to the common gate terminal 130.

The common gate terminal 130 may be configured to receive the input voltage VIN.

The common drain terminal 140 may be connected to one ends of the n-channel-side two-dimensional phase change material layer 111, the n-channel two-dimensional semiconductor material layer 112, the n-channel-side first oxide material layer 114, an n-channel-side second oxide material layer 115, a second spacer 152, the p-channel-side two-dimensional phase change material layer 121, the p-channel two-dimensional semiconductor material layer 122, the p-channel-side first oxide material layer 124, and a p-channel-side second oxide material layer 125.

The n-type ternary MOSFET region 110 may be a region having similar properties to a conventional n-MOSFET, and the p-type ternary MOSFET region 120 may be a region having similar properties to a conventional p-MOSFET. However, the n-type ternary MOSFET region 110 and the p-type ternary MOSFET region 120 may be driven similarly to a conventional n-MOSFET and a conventional p-MOSFET, respectively, but may not be driven completely identically.

The n-type ternary MOSFET region 110 may be stacked on the bottom of the common gate terminal 130, and the p-type ternary MOSFET region 120 may be stacked on the top of the common gate terminal 130, but the present disclosure is not limited thereto.

On the other hand, the n-type ternary MOSFET region 110 may be stacked on the top of the common gate terminal 130, and the p-type ternary MOSFET region 120 may be stacked on the bottom of the common gate terminal 130.

The ternary CMOS device 100 may further include a CMOS input terminal 101 and a CMOS output terminal 102.

The CMOS input terminal 101 may be electrically connected to the common gate terminal 130 such that the common input voltage VIN is input to the common gate terminal 130. The CMOS output terminal 102 may be connected to the common drain terminal 140 to output a common output voltage V_{OUT}.

The common gate terminal 130, the common drain terminal 140, the first source terminal 113, and the second source terminal 123 may be formed by depositing metal through a deposition technique such as an E-beam evaporator after patterning is performed through an exposure process.

The n-channel-side first oxide material layer 114 may be a first oxide material layer stacked on the top of the n-channel two-dimensional semiconductor material layer 112 and the bottom of the common gate terminal 130 to be positioned between the n-channel two-dimensional semiconductor material layer 112 and the common gate terminal 130. The n-channel-side first oxide material layer 114 may serve to electrically isolate the n-channel two-dimensional semiconductor material layer 112 and the common gate terminal 130.

The n-channel two-dimensional semiconductor material layer 112 may be stacked on the top of the n-channel-side two-dimensional phase change material layer 111.

The n-channel-side first oxide material layer 114 may be stacked on the top of the n-channel two-dimensional semiconductor material layer 112.

The common gate terminal 130 may be connected to the top of the n-channel-side first oxide material layer 114.

The p-channel-side first oxide material layer 124 may be a first oxide material layer stacked on the bottom of the p-channel two-dimensional semiconductor material layer 122 and the top of the common gate terminal 130 to be positioned between the p-channel two-dimensional semiconductor material layer 122 and the common gate terminal 130. The p-channel-side first oxide material layer 124 may serve to electrically isolate the p-channel two-dimensional semiconductor material layer 122 and the common gate terminal 130.

The p-channel two-dimensional semiconductor material layer 122 may be stacked on the bottom of the p-channel-side two-dimensional phase change material layer 121.

The p-channel-side first oxide material layer 124 may be stacked on the bottom of the p-channel two-dimensional semiconductor material layer 122.

The common gate terminal 130 may be connected to the bottom of the p-channel-side first oxide material layer 124 and arranged between the p-type ternary MOSFET region 120 and the n-type ternary MOSFET region 110.

The n-channel-side first oxide material layer 114, the n-channel-side second oxide material layer 115, the p-channel-side first oxide material layer 124, and the p-channel-side second oxide material layer 125 may be formed of a high-k material with a large dielectric constant (e.g., Al₂O₃ or HfO₂).

The n-channel-side first oxide material layer 114, the n-channel-side second oxide material layer 115, the p-channel-side first oxide material layer 124, and the p-channel-side second oxide material layer 125 may be formed by deposition via Atomic Layer Deposition (ALD), but the present disclosure is not limited thereto.

A first spacer 151 may include an insulating material. The first spacer 151 may be connected to the common gate terminal 130 at one end thereof. The first spacer 151 may be provided between the p-type ternary MOSFET region 120 and the n-type ternary MOSFET region 110.

The first spacer 151 may be stacked on the top of the first source terminal 113 and the top of the n-channel-side first oxide material layer 114. The first spacer 151 may be stacked on the bottom of the second source terminal 123 and the bottom of the p-channel-side first oxide material layer 124.

The second spacer 152 may include an insulating material. The second spacer 152 may be connected to the common gate terminal 130 at one end of the second spacer 152 and connected to the common drain terminal 140 at the other end of the second spacer 152. The second spacer 152 may be provided between the p-type ternary MOSFET region 120 and the n-type ternary MOSFET region 110.

The second spacer 152 may be stacked on the top of the n-channel-side first oxide material layer 114 and may be stacked on the bottom of the p-channel-side first oxide material layer 124.

A method of fabricating the above-described ternary CMOS device 100 may include depositing the n-channel two-dimensional semiconductor material layer 112 on the top of the n-channel-side two-dimensional phase change material layer 111.

The method of fabricating the ternary CMOS device 100 may further include depositing the n-channel-side first oxide material layer 114 on the top of the n-channel two-dimensional semiconductor material layer 112.

The method of fabricating the ternary CMOS device 100 may further include depositing the first spacer 151 and the second spacer 152 on the top of the n-channel-side first oxide material layer 114.

The method of fabricating the ternary CMOS device 100 may further include connecting the common gate terminal 130 to the top of the n-channel-side first oxide material layer 114.

The method for fabricating the ternary CMOS device 100 may further include depositing the p-channel-side first oxide material layer 124 on the top of the common gate terminal 130, the top of the first spacer 151, the top of the second spacer 152.

The method of fabricating the ternary CMOS device 100 may further include depositing the p-channel two-dimensional semiconductor material layer 122 on the top of the p-channel-side first oxide material layer 124.

The method of fabricating the ternary CMOS device 100 may further include depositing the p-channel-side two-dimensional phase change material layer 121 on the top of the p-channel two-dimensional semiconductor material layer 122.

On the other hand, when the n-type ternary MOSFET region 110 is stacked on the top of the common gate terminal 130 and the p-type ternary MOSFET region 120 is stacked on the bottom of the common gate terminal 130, the order of the stacking operations in the method for fabricating the ternary CMOS device 100 as described above may be reversed.

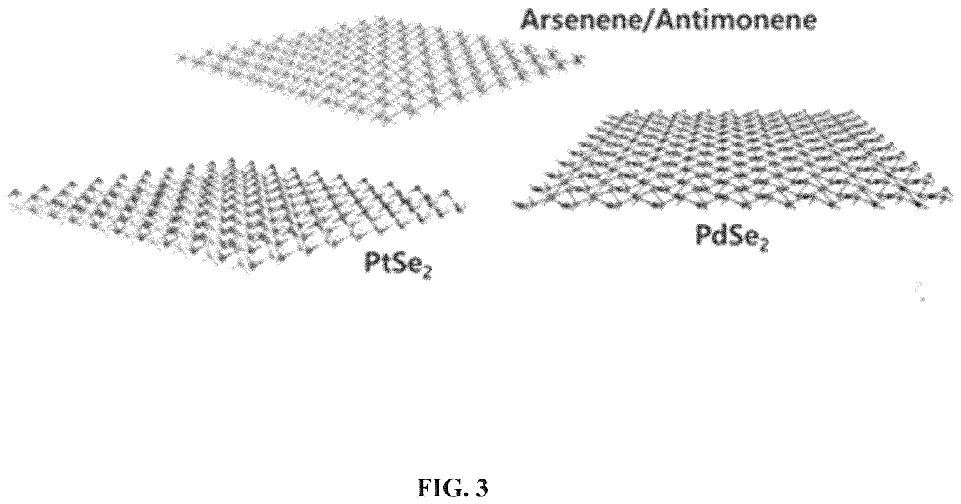

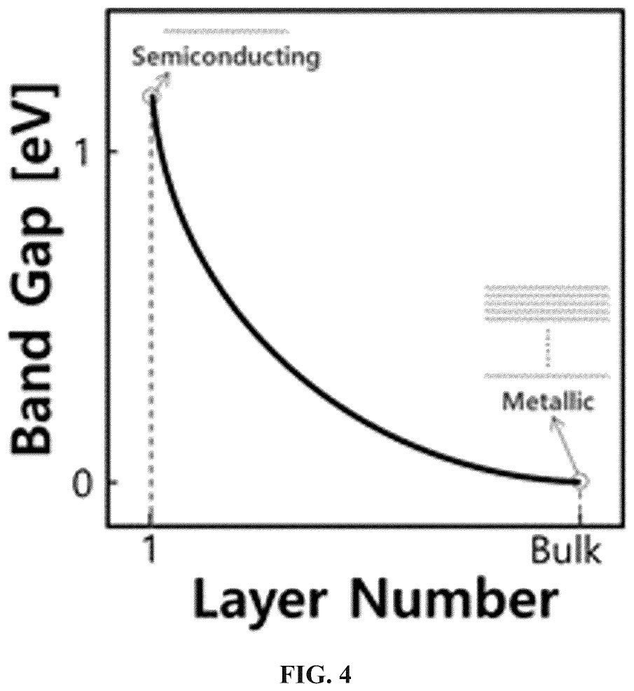

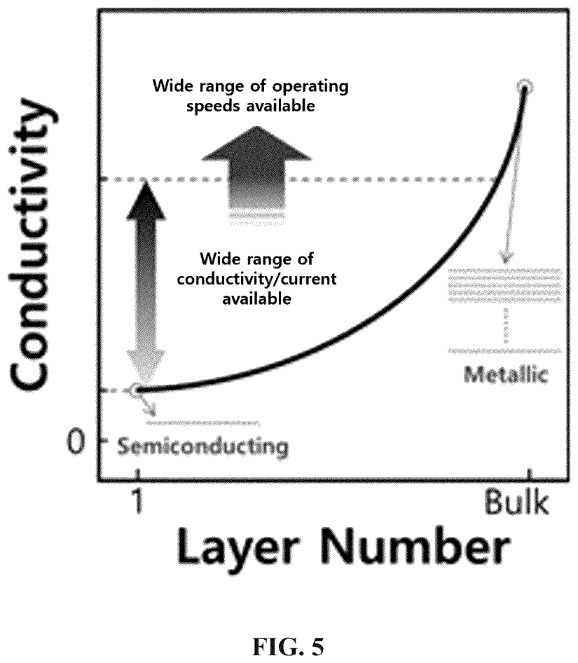

FIG. 3 is a diagram illustrating two-dimensional phase change materials, FIG. 4 is a graph for describing a two-dimensional phase change material having a decreasing band gap with increasing thickness, and FIG. 5 is a graph for describing a two-dimensional phase change material having an increasing conductivity with increasing thickness.

Referring to FIGS. 3, 4, and 5, the two-dimensional phase change material layer may be formed of a two-dimensional phase change material having a decreasing band gap as the thickness of the layer increases.

The two-dimensional phase change material layer may be formed of a two-dimensional material that exhibits a phase transition from a semiconductor to a conductor as a 2D phase transition channel as illustrated in FIG. 3 with a change in thickness.

The two-dimensional phase change material layer may be formed of transition metal dichalcogenides (TMDs) having a decreasing band gap as the thickness of the layer increases. However, the two-dimensional phase change material is not necessarily limited to transition metal chalcogenides.

The two-dimensional phase change material layer may be formed of at least one of PtSe₂ (Platinum Diselenide) and PdSe₂ (Palladium Diselenide). However, the two-dimensional phase change material is not limited to the aforementioned materials.

For example, the two-dimensional phase change material layer may be arsenene, which is a two-dimensional phase change material composed of single atoms, is an allotrope of arsenic (As) and has a two-dimensional structure. Furthermore, the two-dimensional phase change material layer may be antimonene, which is a two-dimensional phase change material composed of single atoms, is an allotrope of antimony (Sb), and has a two-dimensional structure.

The two-dimensional phase change materials such as PdSe₂, PtSe₂, arsenene, and antimonene have a band gap of more than 1 eV in the monolayer, as shown in FIG. 4, exhibiting semiconducting property, but as the thickness increases, the band gap decreases and becomes zero, showing a phase transition phenomenon of exhibiting metallic property.

By utilizing the phase change properties with a change in thickness in the two-dimensional phase change material as described above, it is possible to secure a wide range of conductivity and current by controlling the thickness, as shown in FIG. 5, enabling a wide range of operating speeds with the same device structure and process method, enabling T-CMOS technology with a wide range of applications from ultra-low power to high performance.

In addition, two-dimensional phase change materials may be grown at low temperatures and be semiconductor materials capable of enabling top integration under process conditions that do not deteriorate the Si CMOS properties and reliability, resulting in promising materials for monolithic 3D integration technology, which may further improve the integration of devices.

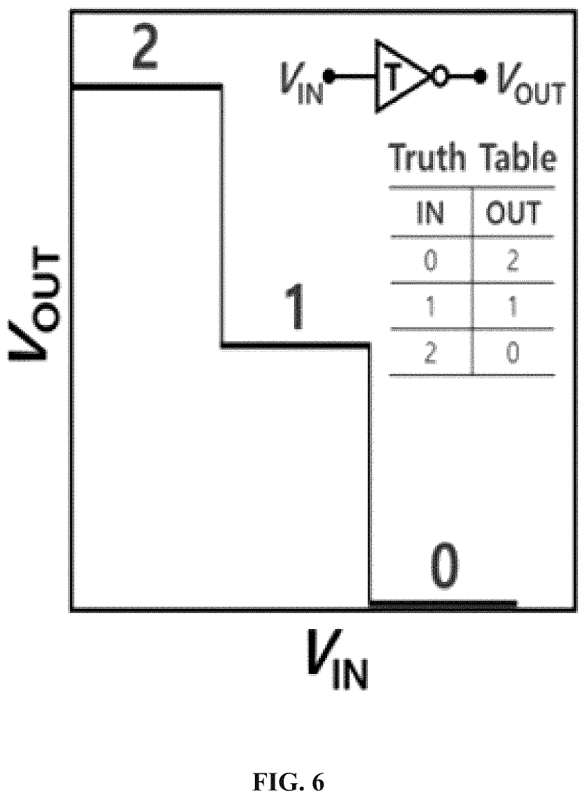

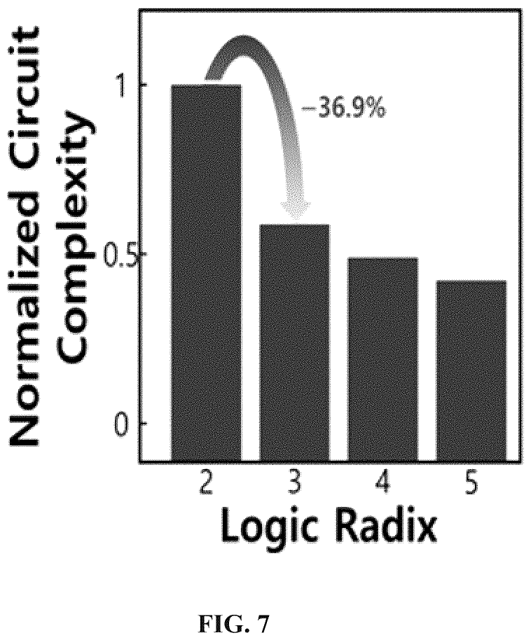

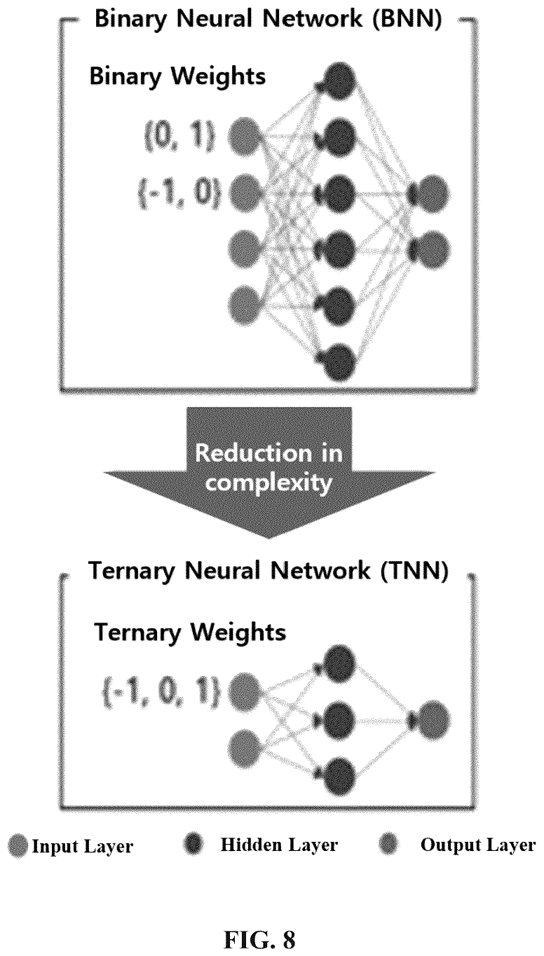

FIG. 6 is a diagram illustrating three states implemented in a ternary inverter, FIG. 7 is a diagram for describing a ternary device in which circuit complexity decreases with an increase in logic digits compared to the prior art, and FIG. 8 is a diagram for describing a simplification of an artificial neural network connection by the introduction of a ternary device.

Referring to FIGS. 6, 7, and 8, the advantages of devices that utilize ternary operations over devices that utilize traditional binary operations may be seen.

The ternary device shown in FIG. 6 represents information as a ternary series of 0s, 1s, and 2s, which may dramatically improve power consumption by reducing the amount of information that needs to be processed compared to traditional binary devices.

By switching the representation of information from bits in binary devices to trits in ternary devices, the voltage required for the state transition in FIG. 6 is half that of a conventional binary, and 2 bits may be represented by 1 trit, which dramatically reduces the circuit complexity, as shown in FIG. 7, enabling a dramatic reduction in power consumption.

Also, in the implementation of artificial neural networks, which has been actively researched in recent years, the introduction of ternary weights {−1, 0, 1} instead of the conventional binary weights {0, 1}, as shown in FIG. 8, may simplify circuit connections and reduce power consumption.

The implementation of the Ternary Inverter (T-Inverter) shown in FIG. 6 is needed for representing information in ternary with these advantages. In the past, various studies have been conducted to distribute a drive voltage V_{DD} to form the intermediate state V_{DD}/2, but this approach has many problems.

For example, a technique of using the stepped current-voltage characteristic due to multiple threshold voltages in the on-state of the device by forming a quantum dot (QD) on the gate oxide in Si MOSFET to implement multiple threshold voltages by resonant tunneling from the Si channel to the QD is difficult to implement a stable constant current due to the scattering of threshold voltage caused by uneven QD formation. This has the problem that a constant current is formed in the ON state of the device, resulting in very large static power consumption in the additional state. In addition, it is difficult to reduce power consumption by scaling an operating voltage V_{DD} due to the implementation of multiple threshold voltages.

The technology using the negative differential resistance of the on-state of the device, which is implemented at the level of small flakes obtained by mechanical peeling technique by utilizing the negative differential resistance by tunneling in a two-dimensional material heterojunction structure, has the problem that the static power consumption in the additional state is very large due to the formation of a constant current in the on-state of the device. Also, the implementation of multiple threshold voltages makes it difficult to reduce power consumption by operating voltage (V_{DD}) scaling.

A technology that uses a stepped current-voltage characteristic due to multiple threshold voltages in the ON state of a device by implementing multiple threshold voltages based on the Mobility Edge Quantisation Effect principle using ZnO composites has the problem that a static current is formed in the ON state of the device and the static power consumption is very large in the additional state. Also, the implementation of multiple threshold voltages makes it difficult to reduce power consumption by operating voltage (V_{DD}) scaling.

The technology of utilizing the constant current in the OFF state of the device by forming a local PN junction at the bottom of a channel in Si MOSFET to implement a small constant current component by tunneling independent of a gate voltage has the problem that it is only suitable for ultra-low power applications because it utilizes a small constant current in the OFF state of the device. Therefore, it may be desirable to implement a CMOS device capable of ternary operation in a new way.

The existing Ternary CMOS (T-CMOS) device has a clear limitation in its application range, but the illustrated ternary CMOS device 100 supports a wide range of operating speeds and may be utilized for a variety of purposes from ultra-low power to high performance.

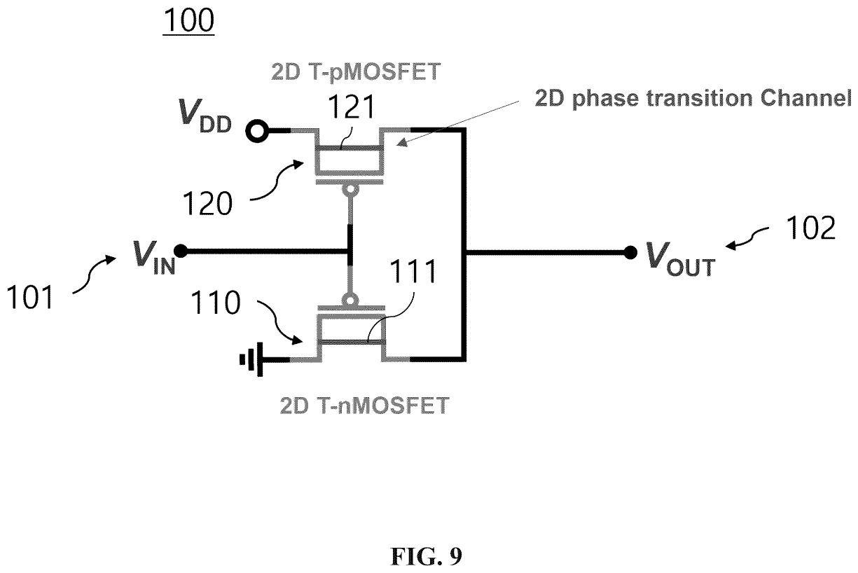

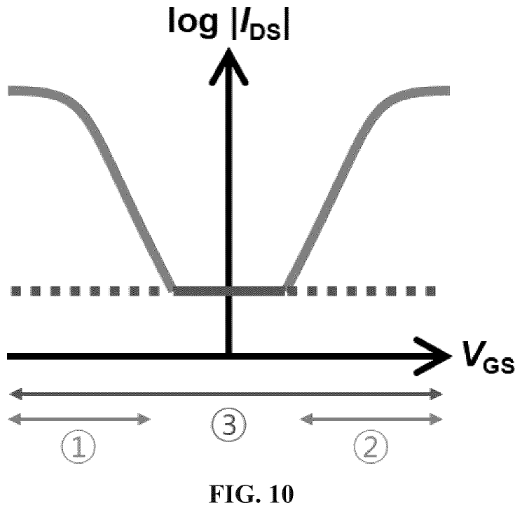

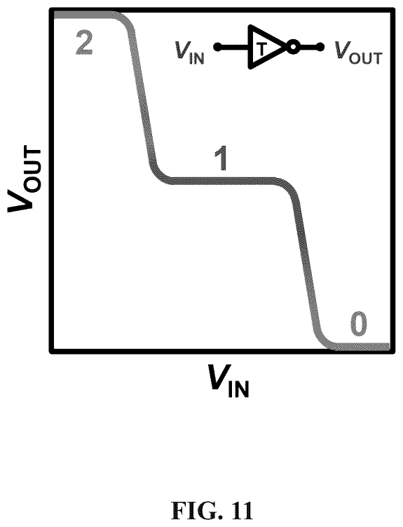

FIG. 9 is a circuit diagram showing the characteristics of a ternary CMOS device according to an embodiment, FIG. 10 is a graph showing a current flowing via a ternary CMOS device according to a voltage applied to the gate, and FIG. 11 is a graph showing the input/output characteristics of a ternary CMOS device according to an embodiment.

Referring to FIGS. 9, 10 and 11, as seen from the illustrated I_{DS}-V_{GS} characteristics, the two-dimensional phase change material layer may generate a certain level of constant current in all operating ranges regardless of the On/Off of the two-dimensional n/pMOSFETs. When both of the two-dimensional n/pMOSFETs are in the Off state, an intermediate state may be generated in the ternary CMOS device 100, that is, the T-CMOS inverter, under the influence of the two-dimensional phase change material layer as illustrated in FIG. 11.

The ternary CMOS device 100 may utilize a constant current in the off state of the device to implement a ternary intermediate state. In this case, the constant current utilized may not be a current due to tunneling in Si-based junction, but may be a current flowing via the Schottky junction of the Source/Drain metal and the undoped two-dimensional material. The ternary CMOS device 100 according to an embodiment is able to implement a constant current more robustly and stably because there is no process dispersion due to doping.

Referring to the I_{DS}-V_{GS} curve illustrated in FIG. 10, it may be seen that \textcircled{1} in the range of a negative gate voltage, the p-type ternary MOSFET is turned on and the n-type ternary MOSFET is turned off, as the gate-source voltage V_{GS} increases, the current flows via the p-channel two-dimensional semiconductor material layer 122, and at a certain point, the I_{DS} stops increasing and becomes saturated.

In addition, \textcircled{2} in the range of a positive gate voltage, the n-type ternary MOSFET is turned on and the p-type ternary MOSFET is turned off, and as a gate-source voltage (V_{GS}) increases, more current flows into the n-channel two-dimensional semiconductor material layer 112, and the I_{DS} may increase and saturate at a certain point.

Furthermore, \textcircled{3} it may be seen in the full range of a gate voltage that a constant amount of current flows in the two-dimensional phase change material layer for all gate-source voltages V_{GS}. In this case, the current may always be present even in the range of a gate-source voltage (V_{GS}) when both the n-type ternary MOSFET and the p-type ternary MOSFET are turned off.

Referring to FIG. 11, the input/output characteristics of the ternary CMOS device 100 according to an embodiment may be seen.

When a voltage input to the CMOS input terminal 101 is less than a first reference voltage, the CMOS output terminal 102 may output a maximum voltage with a certain magnitude.

When the voltage input to the CMOS input terminal 101 is equal to or greater than a second reference voltage and less than a third reference voltage, the CMOS output terminal 102 may output an intermediate voltage with a certain magnitude.

Because the constant current always flows through the two-dimensional phase change material layer regardless of the gate voltage, the constant current may generate a new intermediate state to enable the functioning of the ternary CMOS device 100. Unlike previous T-CMOS studies using a tunneling current, the ternary CMOS device 100 according to an embodiment may use a current through a Schottky junction between a source/drain metal and an undoped two-dimensional material, thus leading to a constant current with high stability.

When a voltage input to the CMOS input terminal 101 is greater than a fourth reference voltage, the CMOS output terminal 102 may be configured to output no voltage.

The above description illustrates the disclosure. Embodiments of the disclosure are described above, and the disclosure may be used in other various combinations and alterations of the embodiments, and environments. The disclosure may be changed or modified within a range equivalent to what is described above and/or a range of technologies or knowledge of ordinary skill in the art. The aforementioned embodiments of the disclosure are for explaining the best modes to practice the technical idea of the disclosure, and many different modifications thereto may be made for a specific application area and usage. Accordingly, the embodiments of the disclosure are not intended to limit the scope of the disclosure to what are disclosed above. The appended claims are to be interpreted as including other embodiments.

According to an aspect of the present disclosure, it is possible to performing ternary operations.

In addition, according to another aspect of the present disclosure, it is possible to provide a ternary CMOS device available for various purposes from an ultra-low power environment to a high-performance environment by supporting a wide range of operating speeds.

In addition, according to another aspect of the present disclosure, it is possible to provide a ternary CMOS device capable of implementing a constant current more robustly and stably because there is no process dispersion due to doping.

In addition, according to another aspect of the present disclosure, it is possible to provide a ternary CMOS device capable of using a semiconductor material capable of enabling top integration under process conditions that do not deteriorate the characteristics and reliability of Si-based CMOS to increase the integration density of a device.

Meanwhile, the effects obtainable from the present disclosure are not limited to the aforementioned effects, and any other effects not mentioned herein will be clearly understood from the following description by those skilled in the art to which the present disclosure pertains.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A ternary CMOS device comprising: a common gate terminal configured such that an input voltage is applied to the common gate terminal; and
two MOSFET regions,
wherein each of the MOSFET regions includes
a two-dimensional phase change material layer formed of a two-dimensional phase change material;
a two-dimensional semiconductor material layer formed of a two-dimensional semiconductor material having a characteristic of changing into a conductor by a voltage change without separate doping and stacked on either a top or bottom of the two-dimensional phase change material layer;
a common drain terminal connected to one end of the two-dimensional phase change material layer and one end of the two-dimensional semiconductor material layer; and
a source terminal connected to the other end of the two-dimensional phase change material layer and the other end of the two-dimensional semiconductor material layer.

2. The ternary CMOS device of claim 1, wherein the two-dimensional phase change material layer is configured to allow a constant current to flow between the common drain terminal and the source terminal regardless of a magnitude of a voltage applied to the common gate terminal.

3. The ternary CMOS device of claim 1, wherein the two-dimensional phase change material layer is formed of a two-dimensional phase change material having a decreasing band gap as a thickness of the layer increases.

4. The ternary CMOS device of claim 3, wherein the two-dimensional phase change material layer is formed of transition metal dichalcogenides (TMDs) having a decreasing band gap as the thickness of the layer increases.

5. The ternary CMOS device of claim 4, wherein the two-dimensional phase change material layer is formed of at least one of PtSe₂ (Platinum Diselenide) and PdSe₂ (Palladium Diselenide).

6. The ternary CMOS device of claim 3, wherein the two-dimensional phase change material layer is formed of at least one of arsenene which is a two-dimensional phase change material composed of single atoms, is an allotrope of arsenic (As) and has a two-dimensional structure, and antimonene which is a two-dimensional phase change material composed of single atoms, is an allotrope of antimony (Sb) and has a two-dimensional structure.

7. The ternary CMOS device of claim 1, further comprising:
a first oxide material layer stacked between the two-dimensional semiconductor material layer and the common gate terminal to be positioned between the two-dimensional semiconductor material layer and the common gate terminal.

8. The ternary CMOS device of claim 7, further comprising:
a second oxide material layer stacked between the two-dimensional phase change material layer and the two-dimensional semiconductor material layer to be positioned between the two-dimensional phase change material layer and the two-dimensional semiconductor material layer.

9. The ternary CMOS device of claim 1, wherein one of the two MOSFET regions is an n-type ternary MOSFET region and the other of the two MOSFET regions is a p-type ternary MOSFET region,
wherein the n-type ternary MOSFET region includes an n-channel two-dimensional semiconductor material layer formed of a two-dimensional semiconductor material having a characteristic of changing into an n-type conductor by a voltage change without separate doping, and
wherein the p-type ternary MOSFET region includes a p-channel two-dimensional semiconductor material layer formed of a two-dimensional semiconductor material having a characteristic of changing into a p-type conductor by a voltage change without separate doping.

10. The ternary CMOS device of claim 9, wherein the n-type ternary MOSFET region includes:
an n-channel-side two-dimensional phase change material layer formed of a two-dimensional phase change material stacked on either a top or bottom of the n-channel two-dimensional semiconductor material layer; and
a first source terminal connected to the other end of the n-channel-side two-dimensional phase change material layer and the other end of the n-channel two-dimensional semiconductor material layer, and
wherein the n-channel two-dimensional semiconductor material layer is provided between the first source terminal and the common drain terminal,
wherein the n-channel-side two-dimensional phase change material layer is provided between the first source terminal and the common drain terminal, and is configured to allow a constant current to flow between the common drain terminal and the first source terminal regardless of a magnitude of a voltage applied to the common gate terminal.

11. The ternary CMOS device of claim 10, wherein the p-type ternary MOSFET region includes:
an p-channel-side two-dimensional phase change material layer formed of a two-dimensional phase change material stacked on either a top or bottom of the p-channel two-dimensional semiconductor material layer; and
a second source terminal connected to the other end of the p-channel-side two-dimensional phase change material layer and the other end of the p-channel two-dimensional semiconductor material layer, and
wherein the p-channel two-dimensional semiconductor material layer is provided between the second source terminal and the common drain terminal,
wherein the p-channel-side two-dimensional phase change material layer is provided between the second source terminal and the common drain terminal, and is configured to allow a constant current to flow between the common drain terminal and the second source terminal regardless of a magnitude of a voltage applied to the common gate terminal.

12. The ternary CMOS device of claim 11, further comprising:
a CMOS input terminal connected to the common gate terminal and configured to input a common input voltage to the common gate terminal; and
a CMOS output terminal connected to the common drain terminal and configured to output a common output voltage.

13. The ternary CMOS device of claim 12, wherein the CMOS output terminal is configured to:
output a maximum voltage with a predetermined magnitude when a voltage input to the CMOS input terminal is less than a first reference voltage;
output an intermediate voltage with a predetermined magnitude when the voltage input to the CMOS input terminal is greater than or equal to a second reference voltage and less than or equal to a third reference voltage; and
output no voltage when the voltage input to the CMOS input terminal is greater than or equal to a fourth reference voltage.

14. The ternary CMOS device of claim 11 wherein the n-type ternary MOSFET region is stacked on a bottom of the common gate terminal, and
wherein the p-type ternary MOSFET region is stacked on a top of the common gate terminal.

15. The ternary CMOS device of claim 14, wherein the n-type ternary MOSFET region further includes an n-channel-side first oxide material layer,
wherein the n-channel two-dimensional semiconductor material layer is stacked on a top of the n-channel-side two-dimensional phase change material layer,
wherein the n-channel-side first oxide material layer is stacked on a top of the n-channel two-dimensional semiconductor material layer, and
wherein the common gate terminal is connected to a top of the n-channel-side first oxide material layer.

16. The ternary CMOS device of claim 15, wherein the p-type ternary MOSFET region further includes a p-channel-side first oxide material layer,
wherein the p-channel two-dimensional semiconductor material layer is stacked on a bottom of the p-channel-side two-dimensional phase change material layer,
wherein the p-channel-side first oxide material layer is stacked on a bottom of the p-channel two-dimensional semiconductor material layer, and
wherein the common gate terminal is connected to a bottom of the p-channel-side first oxide material layer and provided between the p-type ternary MOSFET region and the n-type ternary MOSFET region.

17. The ternary CMOS device of claim 16, further comprising:
a first spacer formed of an insulating material, connected to the common gate terminal at one end of the first spacer, and provided between the p-type ternary MOSFET region and the n-type ternary MOSFET region; and
a second spacer formed of an insulating material, connected to the common gate terminal at one end of the second spacer, connected to the common drain terminal at the other end of the second spacer, and provided between the p-type ternary MOSFET region and the n-type ternary MOSFET region,
wherein the first spacer is stacked on a top of the first source terminal and a top of the n-channel-side first oxide material layer, and on a bottom of the second source terminal and a bottom of the p-channel-side first oxide material layer, and
wherein the second spacer is stacked on the top of the n-channel-side first oxide material layer, and on the bottom of the p-channel-side first oxide material layer.

18. A method of fabricating the ternary CMOS device of claim 17, comprising:
depositing the n-channel two-dimensional semiconductor material layer on a top of the n-channel-side two-dimensional phase change material layer; and
depositing the n-channel-side first oxide material layer on a top of the n-channel two-dimensional semiconductor material layer.

19. The method of claim 18, further comprising:
depositing the first spacer and the second spacer on the top of the n-channel-side first oxide material layer; and
connecting the common gate terminal to the top of the n-channel-side first oxide material layer.

20. The method of claim 19, further comprising:
depositing the p-channel-side first oxide material layer on a top of the common gate terminal, a top of the first spacer, and a top of the second spacer;
depositing the p-channel two-dimensional semiconductor material layer on a top of the p-channel-side first oxide material layer; and
depositing the p-channel-side two-dimensional phase change material layer on the top of the p-channel two-dimensional semiconductor material layer.
